(19) United States
(12) Patent Application Publication
(10) Pub. No.: US 2020/0214117 A1
(43) Pub. Date: Jul. 2, 2020

(54) WEARABLE STATIC ELECTRICITY REMOVING DEVICE

(71) Applicant: Chiu-Hsia Chang, Taipei City (TW)

(72) Inventor: Chiu-Hsia Chang, Taipei City (TW)

(21) Appl. No.: 16/233,126

(22) Filed: Dec. 27, 2018

(51) Int. Cl. H05F 3/02; G08B 7/06; H01L 27/02; A41D 13/008; A41D 20/00

(52) U.S. Cl. CPC H05F 3/02; G08B 7/06; A41D 20/00; A41D 13/008; H01L 27/0255

(57) ABSTRACT

A wearable static electricity removing device includes a portable device which has a metal sheet; a current limiter for limiting a current flow therethrough; .a high impedance resistor connected to the metal sheet; an impedance of the high impedance resistor being greater than that of the current limiter; a conductive wire having an end connected to the current limiter and the high impedance resistor; and another end of the conductive wire being grounded. In use, when the body of the user has static electricity, the static electricity will pass through the current limiter and then flows to the ground through the conductive wire so as to have the effect of removing the static electricity; and when the user contacts a high voltage which causes the current limiter to breakdown to protect the user, and the static electricity from the user flows through the high impedance resistor.

### FIELD OF THE INVENTION

The present invention is related to removing of static electricity, and in particular to a wearable static electricity removing device

### BACKGROUND OF THE INVENTION

In electronic factories, or in dry areas, large static electricity possibly generates and is accumulated. Large static electricity will generate surge power to hurt the users or destroy devices. Therefore, it is necessary to remove the static electricity.

A ring, such as wristband or bracelet or leg band or leg ring, is used to remove static electricity. In these devices, one end has a conductive wire 40′which is grounded and another end thereof is a metal sheet 10′which contacts bodies of users. The conductive wire 40′is serially connected to a resistor 30 of 1 Ω, see FIG. 1, which is to avoid that the user is in contact to a very high voltage (for example, 220V or 330V) to hurt himself or herself. When the current is over 0.5 A, the resistor 30 will burnt and thus opened so as to avoid the user to contact high voltage current. The above mentioned rings with resistor 30 of 1 MΩ will have a residual static electricity of several hundred voltages. The static electricity will release to ground through the rings. High voltage of the static electricity will decay from 1 kV to several hundred voltages and then to 100V-200V. The time required is long. However, from regulations of IEC61000-4-2, the time period for discharging the static electricity is about 0.1 μs, however, the conventional ring for discharging the static electricity has a time about 1 second or even more long time period is need, while in this period, if the user takes an electronic device which is easily to be destroyed by static electricity, it is possible that the device is destroyed by the static electricity in user's body.

Because the manufacturing process of semiconductor will enter into a process of 5 nanometers, and thus the elements under these process are more and more sensitive to the static electricity. The ability of HBM endurance for IC components is reduced from 4 kV to 500V. Thereby, the ability to prevent the static electricity is an important consideration for IC manufacturing and packaging. Furthermore for RF components or other static electricity sensitive components, they are easily to be destroyed even the voltage of the static electricity is under 50V. As a result, the conventional static electricity preventing rings are not sufficient to protect the operator or the components from impacting of the static electricity.

### SUMMARY OF THE INVENTION

Accordingly, to overcome the defect in the prior art as above said, the present invention provides a wearable static electricity removing device, in that a portable device is installed with a metal sheet. A high impedance resistor and a current limiter are connected to the metal sheet in parallel. The high impedance resistor and the current limiter are connected to a conductive wire which is grounded. An electric static suppression element (such as a TVS diode) may be connected between the metal sheet and the current limiter so as to remove static electricity at human body quickly with a very low residue voltage of about 7V, which does not destroy electronic devices. The structure of the present invention can achieve the effects of protecting users and avoiding residual current to destroy peripheral devices. Furthermore when the user contacts higher voltage, the current limiter will break to protect the user, while the current can flow through the high impedance resistor. If the current is too high, the high impedance resistor may burn out to further protect the user. In the present invention, the LED lamp set can be connected between the electric static suppression element and the current limiter. The light of the LED lamps can show the charge to be positive or negative and the effect of removing the static electricity.

To achieve above object, the present invention provides a wearable static electricity removing device, comprising: a portable device including: a metal sheet for contacting a user's body wearing the portable device; a current limiter for limiting a current flow therethrough; If a predetermined value of current is over, the current limiter will open to cause a circuit having the current limiter to be opened; the current limiter having a left end connected to the metal sheet; a high impedance resistor having a left end connected to the metal sheet; an impedance of the high impedance resistor being greater than that of the current limiter; a conductive wire having a left end connected to a right end of the current limiter and a right end of the high impedance resistor; and a right end of the conductive wire being grounded; therefore, the current limiter and the high impedance resistor being connected parallel between the metal sheet and the conductive wire. In use, the portable device is worn on the body of the user and the metal sheet is in contact to the body of the user; when the body of the user has static electricity, the static electricity will pass through the current limiter and then flows to the ground through the conductive wire so as to have the effect of removing the static electricity. When the user contacts a predetermined high voltage which causes the current limiter to breakdown to protect the user from getting electrically shocked, and the static electricity from the user flows through the high impedance resistor and then to the conductive wire for discharging to ground.

### BRIEF DESCRIPTION OF THE DRAWINGS

FIG. 1 is a circuit showing the prior art static electron ring.

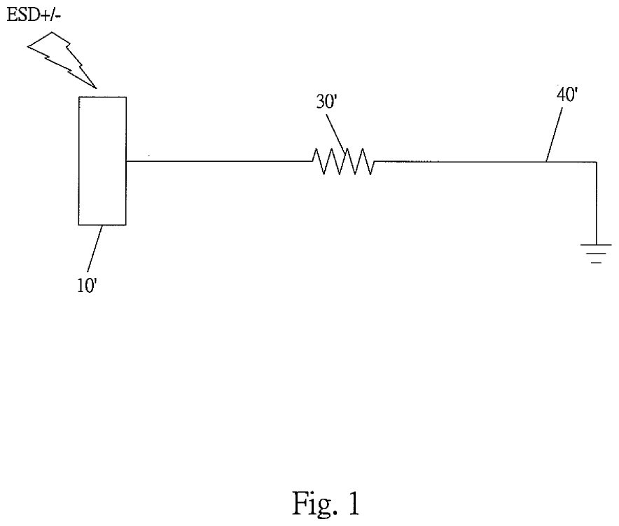

FIG. 2 shows a basic structure according to the present invention.

FIG. 3 shows a circuit according to the present invention.

FIG. 4 is another circuit according to the present invention.

FIG. 5 is a third circuit according to the present invention.

FIG. 6 is a fourth circuit according to the present invention.

FIG. 7 is a fifth circuit according to the present invention.

FIG. 8 is a sixth circuit according to the present invention.

FIG. 9 is a seventh circuit according to the present invention.

FIG. 10 is an eighth circuit according to the present invention.

FIG. 11 is a ninth circuit according to the present invention.

FIG. 12 shows one application of the present invention.

FIG. 13 shows that the current limiter is an inductor limiter.

FIG. 14 shows that the current limier is a ferrite bead limiter.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

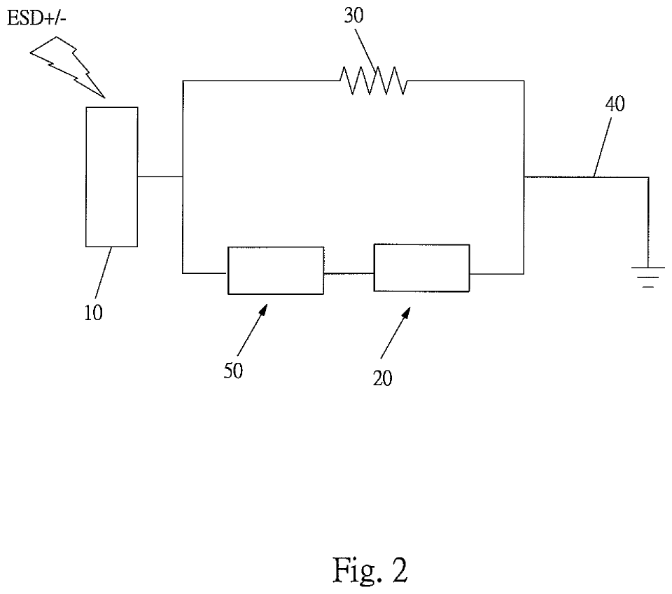

With reference to FIGS. 2 to 14, the structures of the present invention are illustrated. The present invention includes the following elements with reference to FIG. 2.

A portable device I comprises the following elements. A metal sheet 10 serves to contact a user's body wearing the present invention.

A current limiter 20 serves to limit the current flow therethrough. If a predetermined value of current is over, the current limiter will open to cause a circuit having the current limiter to be opened. The current limiter has a left end connected to the metal sheet 10. Preferably, the current limiter 20 breaks at a current smaller than or equal to 0.4 A. Generally, the resistance of the current limiter 20 is smaller than 0.6 Ω. In the following, a fuse is used as an example of the current limiter, however this is not used to confine the scope of the present invention, other elements have the same effect are useable in the present invention and are within the scope of the present invention.

A high impedance resistor 30 has a left end connected to the metal sheet 10. An impedance of the high impedance resistor 30 is greater than that of the current limiter 20. Preferably, a resistor of the high impedance resistor 30 is 1 MΩ. The high impedance resistor 30 can bear a current of 0.5 A.

A conductive wire 40 has a left side connected to a right end of the current limiter 20 and a right end of the high impedance resistor 30. A right end of the conductive wire 40 is grounded.

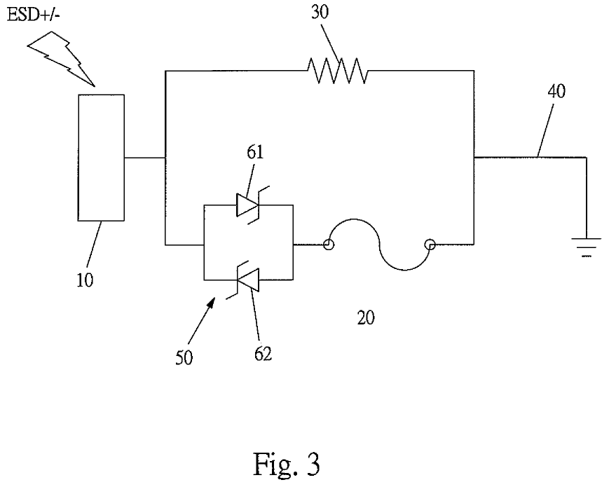

Therefore, the current limiter 20 and the high impedance resistor 30 are connected parallel between the metal sheet 10 and the conductive wire 40. An electric static suppression element 50 is connected between the current limiter 20 and the metal sheet 10, see FIG. 3. The impedance of the high impedance resistor 30 is greater than a dynamic resistance of the electric static suppression element 50.

The portable device 1 is worn on the body of the user and the metal sheet 10 is in contact to the body of the user. A right end of the conductive wire 40 is grounded. When the body of the user has static electricity, because the resistances of the electric static suppression element 50 and the current limiter 20 are lower than that of the high impedance resistor 30, the static electricity will pass through the electric static suppression element 50 and the current limiter 20 and then flows to the ground through the conductive wire 40 so as to have the effect of removing the static electricity.

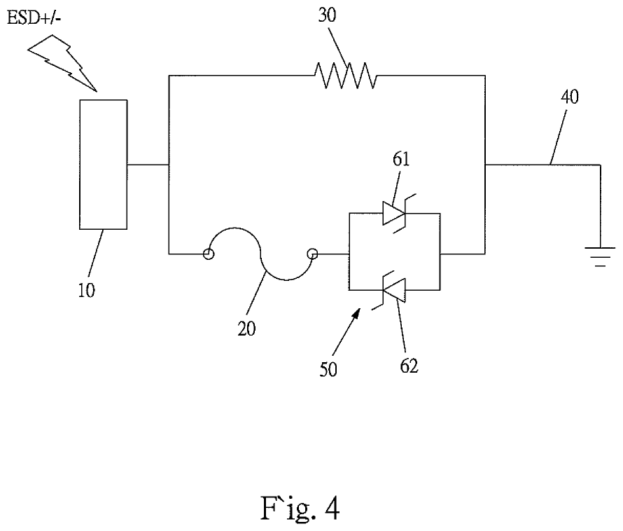

With reference to FIGS. 3 and 4, it is illustrated that the electric static suppression element 50 is formed by parallel connection of two TVS diode (Transient Voltage Suppression diode) 61, 62 which are connected along opposite directions, that is one TVS diode is connected forwardly, and another one is connected reversely. The unidirectional TVS diode can be conducted even the forward bias is near 1V.

Each of the TVSs 61, 62 has a working voltage, a breakdown voltage, and a clamping voltage between the working voltage and the breakdown voltage. Each of the TVS diode has a parasitic capacitor and has directivity and each of the TVS diode is an unidirectional transient voltage suppression.

When the user's body has positive static electricity, the static electricity will flow through the metal sheet 10, the forwardly connected

TVS diode 61 and the conductive wire 40 to ground. Similarly, when the user's body has negative static electricity, the static electricity will flow through the current limiter 20, the reversely connected TVS diode 62 to the body so as to remove the static electricity in the body of the user. The activation speed of the TVS diodes 61, 62 are smaller than 0.1 μs, while in general, a duration for discharging of static elections is smaller than 0.1 μs. Therefore, once the user's body has static electricity, they will be bypassed to the grounds almost at the same time. Furthermore, the present invention can be used to protect the user when the user gets electric shock at a high voltage.

Preferably, the working voltage of the TVS diode is 5V, and the breakdown voltage is 8V. When the electric static voltage is higher than the breakdown voltage of the TVS diodes 61, 62, the TVS diodes 61, 62 will be actuated and at this moment, the internal resistors of the TVS diodes 61, 62 are about 0.1 Ω and the electric static voltage is clamped at about 7V. That is to say, by using the static electricity removing device of the present invention, the static electricity can be conducted to ground at a very short time, about 0.1 μs. Therefore, the user does not worry about that the residual electric charges in his or her body will destroy static electricity sensitive IC components. However, conventional static electricity removing rings with a 1 MΩ resistor have residual charges of several hundred voltages. The static electricity removing device according to the present invention may control the static electricity voltage at a very low value of about 7V. The effect is improved greatly. In the present invention, the endurance current of the current limiter 20 is equal to or smaller than 0.4 A. When a user contacts a very high voltage, such as 110V to 330V, carelessly, the current limiter 20 breaks so that the circuit is opened to protect the user from being hurt electrically. At this moment, the static electricity can flow through the high impedance resistor 30 to the conductive wire 40 to remove the static electricity. Thus dual circuits for removing static electricity have a better effect in removing static electricity. When the current flow continuously or over 0.5 A, the high impedance resistor 30 will burn up to cause the circuit is opened to protect the user from being hurt by high voltage. With reference to FIG. 4, the electric static suppression element 50 may be serially connected between the current limiter 20 and the conductive wire 40.

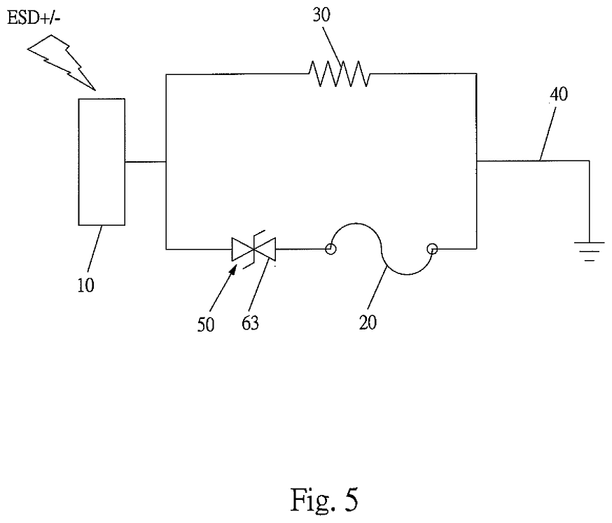

With reference to FIG. 5, the TVS diode is a bidirectional TVS diode 63 so that both positive static electricity and negative static electricity can flow through the bidirectional TVS diode 63.

The bidirectional TVS diode 63 has a working voltage (Vrbw) and a breakdown voltage. The bidirectional TVS diode 63 has a parasitic capacitor.

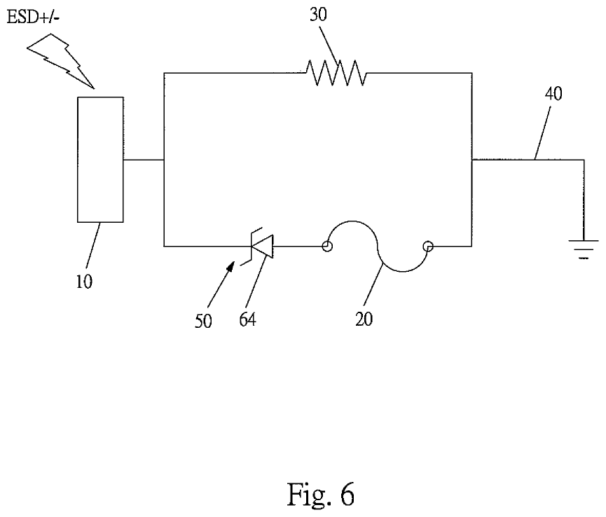

Referring to FIG. 6, the electric static suppression element 50 is a unidirectional TVS diode 64. This arrangement is convenient for determining whether the the TVS diode 64 and the current limiter 20 are burnt by using a measuring meter.

The unidirectional TVS diodes 61, 62, 64 and the bidirectional TVS diode 63 have parasitic capacitance, and furthermore, thee can be passed by positive and negative charges. When a user wears the portable device 1, the value of the static electricity is very low. If we measure the resistances of the TVS diodes 61, 62, 63 and 64, they have the property of capacitors and are opened. When a user has static electricity, the static electricity flows from the metal sheet 10 to the TVS diodes 61, 62, 64, or the bidirectional TVS diode 63. When the voltage of the static electricity is higher than the breakdown voltages of the TVS diodes 61, 62, 64 or the bidirectional TVS diode 63 (for example, 8V, based on the TVS diode used), the TVS diodes 61, 62, 64 and 63 will conduct at a time period about 0.1 μs. Because interior resistors of the TVS diodes 61, 62, 63 and 64 are smaller than 0.1Ω, and thus the static electricity current flows through the TVS diodes 61, 62, 63 and 64 and then through the current limiter 20 and the conductive wire 40 to the ground in a very short time (0.1 μs). The TVS diodes 61, 62, 63 and 64 have clamping voltages, and thus high static voltage (such as several decades KV) are conducted transiently (at a time period of 0.1 μs), while the electron static voltage of the metal sheet 10 is clamped at a value about 7V. The clamping voltage is determined by the property of selected TVS diodes. Preferably, the dynamic impedances of the TVS diodes 61, 62, 63 and 64 are smaller than 0.1 which can present a better effect. By experiments, the TVS diodes and current limiter 20 may suffer from an electric static impact 30 KV and do not burn up. If DC or AC current is near 0.4 A, the current limiter 20 will burn up. In conduction, the unidirectional TVS diodes 61, 62, 64 or the bidirectional TVS diode 63 has an inner impedance of 0.1 Ω, and the inner impedance of the current limiter 20 is small than 0.6Ω. The total impedance is smaller than 0.7 Ω which is very smaller than nu) impedance of the high impedance resistor 30. Therefore, in general, the electric static current flows along the path having the TVS diodes to cause the electric static current is removed very quickly.

The electric static suppression element 50 may be a varistor, a Zener diode or a polymer suppressor. In the present invention, the TVS diodes have better effect in suppressing of static electricity, because they have a quick response, low internal resistors after actuation, high endurance for static electricity, etc.

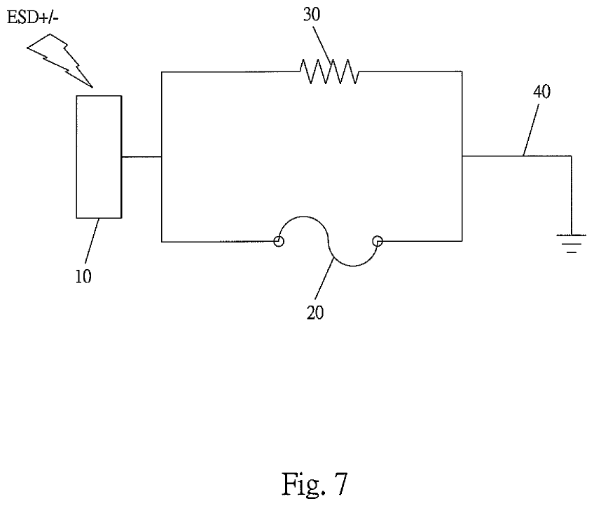

With reference to FIG. 7, in the present invention, the portable device 1 does not have the electric static suppression element 50, but only has the current limiter 20 and the high impedance resistor 30. This has a better effect, but when measuring the resistance between the metal sheet 10 and the conductive wire 40, the resistance almost approaches to 0 Ω and thus it is possible to be considered to be shorted in the internal thereof and thus to be determined to be shorted and thus is irregular.

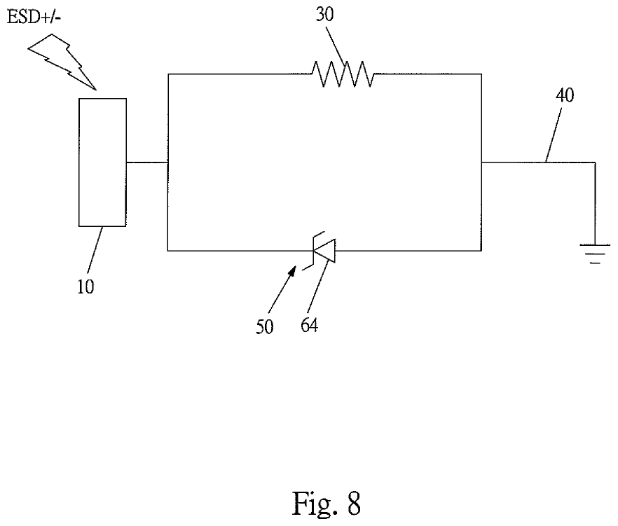

With reference to FIG. 8, the current limiter 20 is not used, only the TVS diode 64 and the high impedance resistor 30 are used, which has the same effect. However, when the user contacts high voltage, the TVS diode 64 will burn up and thus the circuit is shorted circuited. It is not preferably under consideration of safety.

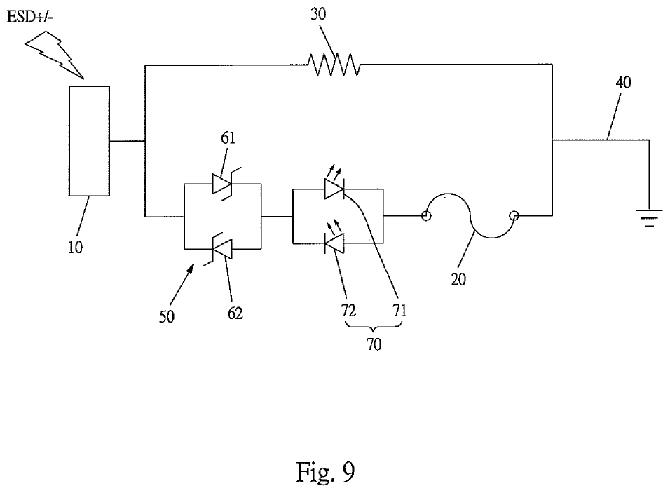

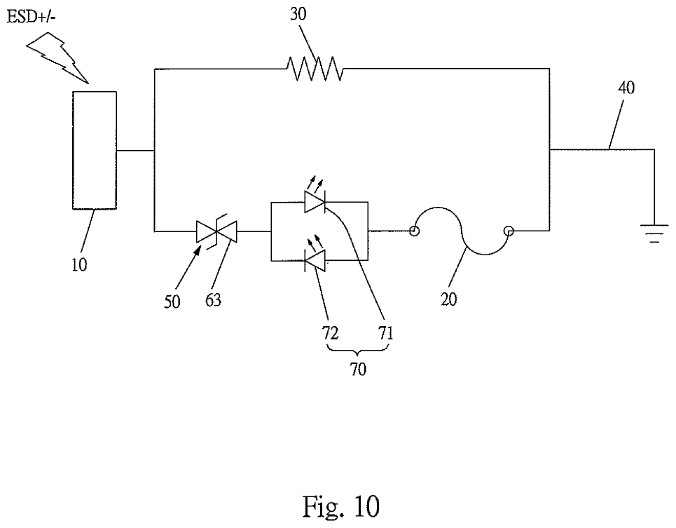

With reference to FIGS. 9 and 10, it is illustrated that an LED lamp set 70 is connected between the electric static suppression element 70 and the current limiter 20. The LED lamp set 70 includes two LED lamps 71, 72, in that, the LED lamp 71 is connected forwardly and the LED lamp 72 are reversely connected. A positive static electricity flows from the metal sheet 10 to the conductive wire 40 through the TVS diode will cause the LED lamp 71 to light up, while a negative static electricity flows from the conductive wire 40 to the metal sheet 10 through the TVS diode will cause the LED lamp 72 to light up. Thereby, the user can know that the static electricity to be cancelled is positive or negative.

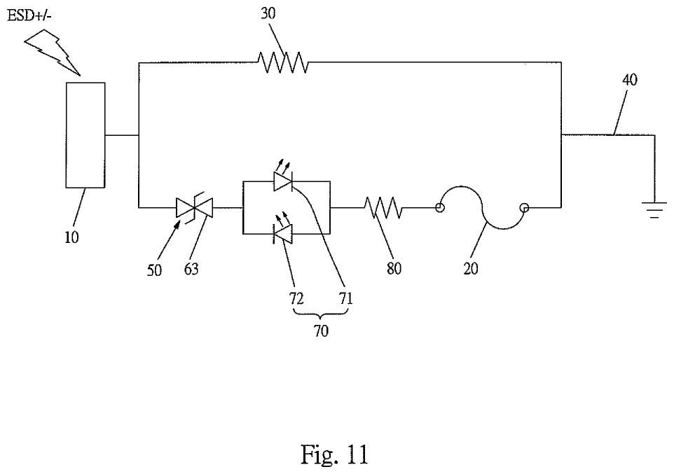

Preferably, the LED lamps 71, 72 have highly intensities and can bear large current so as to bear high static electricity, for example, to bear an Electrostatic Discharge (ESD) to 20 kV-30 kV. If the LED lamp set is a general one, a small resistor 80 (referring to FIG. 11) is connected between the LED lamp set 70 and the current limiter 20. The resistance of the resistor 80 is about dozens of ohms to avoid the LED lamp set 70 is burnt up.

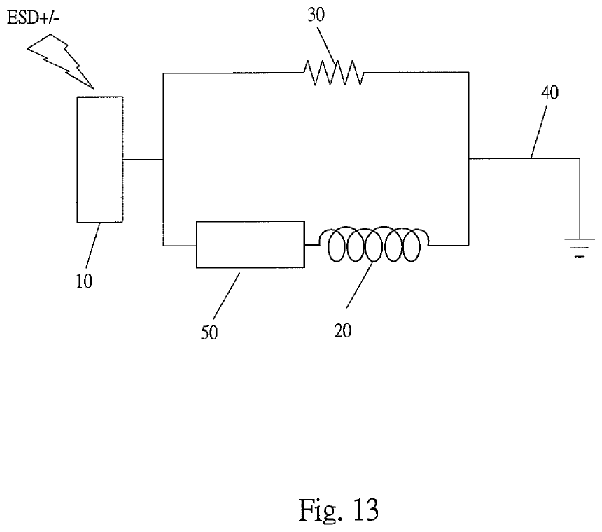

With reference to FIG. 13, it is illustrated that the current limiter 20 is an inductor limiter. The inductor limiter is an inductor which will burn up as a current flowing therethrough is greater than a predetermined value. For example the limiting current is 0.4 A.

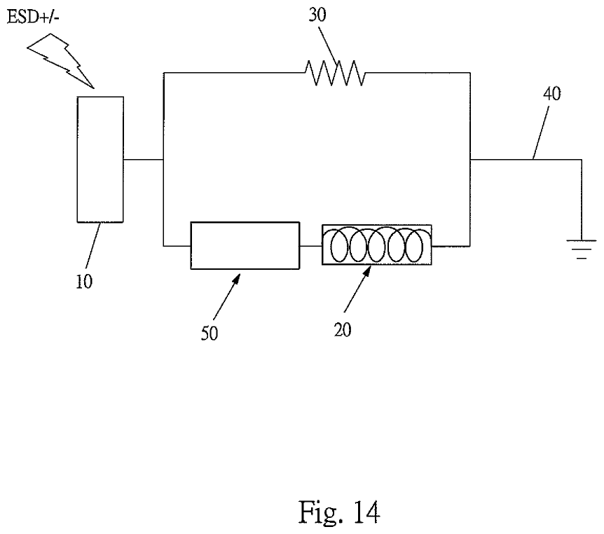

With reference to FIG. 14, it is illustrated that the current limiter 20 is a ferrite bead. The ferrite bead is an inductor enclosing by a sleeve. The sleeve is an iron magnetic material which can conduct static electricity flows therethrough with a large voltage, such as 30 kV, but if a DC or AC current flows therethrough is larger than a predetermined value, such as 0.15 A, it will burn up. Another, the inductor in the ferrite bead is an inductor which will burn up as a current flowing therethrough is greater than a predetermined value. For example the limiting current is 0.4 A. The application of the present invention will be described herein.

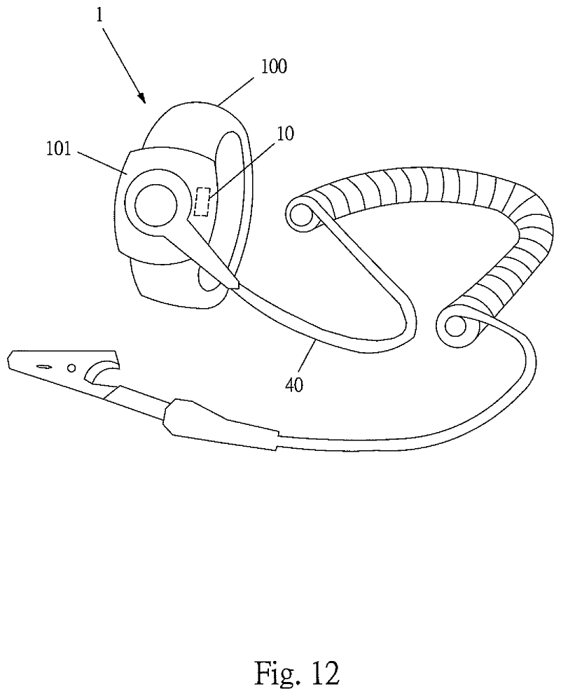

The portable device 1 is a wristband 100 (see FIG. 12). Wristband 100 includes a conductive portion 101. metal sheet 10 exposes out so as to contact user's body. The conductive wire 40 extends out from one end of the wristband 100. The wristband 100 may be a ring only for cancellation of static electricity, or other rings, such as rings for health, rings for communication, watches, intelligent wristbands, etc.

In the present invention, a portable device is installed with a metal sheet. A high impedance resistor and a current limiter are connected to the metal sheet in parallel. The high impedance resistor and the current limiter are connected to a conductive wire which is grounded. An electric static suppression element (such as a TVS diode) may be connected between the metal sheet and the current limiter so as to remove static electricity at human body quickly with a very low residue voltage of about 7V, which does not destroy electronic devices. The structure of the present invention can achieve the effects of protecting users and avoiding residual current to destroy peripheral devices. Furthermore when the user contacts higher voltage, the current limiter will break to protect the user, while the current can flow through the high impedance resistor. If the current is too high, the high impedance resistor may burn out to further protect the user. In the present invention, the LED lamp set can be connected between the electric static suppression element and the current limiter. The light of the LED lamps can show the charge to be positive or negative and the effect of removing the static electricity.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A wearable static electricity removing device, comprising:
a portable device including:
a metal sheet for contacting a user's body wearing the portable device;
a current limiter for limiting a current flow therethrough; If a predetermined value of current is over, the current limiter will open to cause a circuit having the current limiter to be opened; the current limiter having a left end connected to the metal sheet;
a high impedance resistor having a left end connected to the metal sheet; an impedance of the high impedance resistor being greater than that of the current limiter;
a conductive wire having a left end connected to a right end of the current limiter and a right end of the high impedance resistor; and a right end of the conductive wire being grounded; therefore, the current limiter and the high impedance resistor being connected parallel between the metal sheet and the conductive wire;
wherein in use, the portable device is worn on the body of the user and the metal sheet is in contact to the body of the user; when the body of the user has static electricity, the static electricity will pass through the current limiter and then flows to the ground through the conductive wire so as to have the effect of removing the static electricity; and
when the user contacts a predetermined high voltage which causes the current limiter to breakdown to protect the user from getting electrically shocked, and the static electricity from the user flows through the high impedance resistor and then to the conductive wire for discharging to ground.

2. The wearable static electricity removing device as claimed in claim 1, wherein an electric static suppression element is connected between the current limiter and the metal sheet; and an impedance of the high impedance resistor is greater than a resistance of the electric static suppression element.

3. The wearable static electricity removing device as claimed in claim 2, wherein the electric static suppression element is a TVS diode (Transient Voltage Suppression diode) set which includes at least one TVS diode.

4. The wearable static electricity removing device as claimed in claim 3, wherein the TVS diode set is formed by parallel connection of two unidirectional TVS diodes which are connected along opposite directions, that is, one TVS diode is connected forwardly, and another one is connected reversely; and each TVS diode has a directivity and is unidirectional.

5. The wearable static electricity removing device as claimed in claim 4, wherein each of the TVSs has a working voltage, a breakdown voltage, and a clamping voltage between the working voltage and the breakdown voltage.

6. The wearable static electricity removing device as claimed in claim 3, wherein the TVS diode set is a bidirectional TVS diode so that both positive static electricity and negative static electricity can flow through the bidirectional TVS diode.

7. The wearable static electricity removing device as claimed in claim 3, wherein each TVS diode in the TVS diode set has a parasitic capacitance;
if the portable device is worn on human body who has low static electricity, the TVS diode in the TVS diode set has a property of capacitors to cause a circuit having the TVS diode is opened; when the static electricity in the user is large, the static electricity flows from the metal sheet to the TVS diode; when the voltage of the static electricity is higher than a breakdown voltages of the TVS diode in the TVS diode set, the TVS diode set will conduct to cause the static electricity flows through the TVS diode.

8. The wearable static electricity removing device as claimed in claim 2, wherein the electric static suppression element is one of a varistor, a Zener diode, and a polymer suppressor.

9. The wearable static electricity removing device as claimed in claim 2, wherein the current limier is a fuse.

10. The wearable static electricity removing device as claimed in claim 2, wherein the current limiter is an inductor limiter which will burn up as a current flowing therethrough is greater than a predetermined value.

11. The wearable static electricity removing device as claimed in claim 2, wherein the current limiter is a ferrite bead which will burn up as a current flowing therethrough is greater than a predetermined value.

12. The wearable static electricity removing device as claimed in claim 2, wherein an LED lamp set is connected between the electric static suppression element and the current limiter.

13. The wearable static electricity removing device as claimed in claim 12, wherein the LED lamp set includes two LED lamps, a first LED lamp is connected forwardly and a second LED lamp is reversely connected.

14. The wearable static electricity removing device as claimed in claim 12, wherein light color from the first LED lamp is different from that from the second LED lamp.

15. The wearable static electricity removing device as claimed in claim 1, wherein a resistor of the high impedance resistor is 1 MΩ and can bear a current not large than 0.5 MA.
